(19) United States
(12) Patent Application Publication
(10) Pub. No.: US 2002/0090797 A1
(43) Pub. Date: Jul. 11, 2002

(54) Method for protecting insulation corners of shallow trenches by oxidation of poly silicon

(76) Inventors: Hsin-Huei Chen, Miao-Li Hsien (TW); Chong-Jen Huang, San-Chung City (TW); Kuang-Wen Liu, Nan-Tou Hsien (TW); Chih-Hao Wang, Tao Yuan Hsien (TW)

Correspondence Address: Supreme Patent Services, Post Office Box 3318, Saratoga, CA, 95070, US

(21) Appl. No.: 09/757,557

(22) Filed: Jan. 9, 2001

(51) Int. Cl. H01L 21/76

(52) U.S. Cl. 438/437

(57) ABSTRACT

The present invention is the first one to disclose using of a polysilicon layer in lieu of a silicon nitride (Si₃N₄) layer, and forming a spacer as a buffering layer by oxidation of polysilicon in oxidation of shallow trenches to protect insulation corners of the shallow trenches (STI corners). This not only omits the process to form and to remove a polymer spacer, but also protects insulation comers of the shallow trenches by forming the polysilicon spacer by oxidation, thereby avoids exposing of the STI comers which results abnormal electricity conductivity.

### BACKGROUND OF THE INVENTION

1. Field of the Invention

The present invention is related to a method for protecting insulation comers of shallow trenches by forming a spacer as a buffering layer by oxidation of polysilicon in a shallow trench isolation (STI) process. The present invention substitutes polysilicon for conventional silicon nitride layer, especially, when the polysilicon forms an oxide liner, it forms simultaneously a spacer for buffering. This can reduce processing steps in shallow trench isolation (STI) as compared to the conventional process wherein a step of forming a spacer must be added after forming the silicon nitride layer.

2. Description of the Prior Art

In semiconductor wafers, there must be an isolation structure to isolate individual elements in each wafer. Up to date, several semiconductor isolation techniques have been disclosed, including LOCOS, STI, Poly-Buffered LOCOS and framed-mask LOCOS etc. The isolation structures of the above stated techniques all make growing of a field oxidation layer with heat in an isolation area using silicon nitride as a mask, and then the silicon nitride is removed.

By the tendency that elements become smaller and smaller, conventional LOCOS isolation cannot satisfy the process of ULSI today. The main defect of it is resided in a “bird's beak effect”, the trench isolation has more advantages as compared to the conventional LOCOS isolation, hence the trench isolation has gradually taken the place of the conventional LOCOS isolation. Wherein, the shallow trench isolation (STI) firstly forms a shallow trench on a silicon wafer by etching; then oxide is filled in the trench and is made plane.

In the technique of the conventional shallow trench isolation (STI), as is shown in FIG. 1A to 1C, the method of forming the structure from the shallow trench isolation (STI) includes mainly the following steps:

providing a silicon (Si) substrate 101;

making growing of a pad oxide (SiO₂) layer 102;

making growing of a silicon nitride (Si₃N₄) layer 103;

forming a shallow trench area 100;

forming a liner oxide layer 104;

filling the shallow trench area 100 with oxide 105 formed by High Density Plasma—Chemical Vapor Deposition (HDP CVD Oxide Fill);

making the oxide 105 plane.

Wherein, in the step of making growing of the silicon nitride (Si₃N₄) layer 103, a silicon oxide (SiO₂) layer 102 and a silicon nitride (Si₃N₄) layer 103 of polysilicon are formed sequentially on the silicon (Si) substrate 101. In the step of forming the shallow trench area 100, the shallow trench area 100 is formed on the silicon (Si) substrate 101 by etching. In the steps of forming the liner oxide layer 104 on the shallow trench area 100 and filling the shallow trench area 100 with oxide 105 formed by High Density Plasma—Chemical Vapor Deposition in the shallow trench area 100, the shallow trench area 100 is oxidized with a furnace pipe with high temperature to form the liner oxide layer 104, and then the shallow trench area 100 is filled with the oxide 105.

In the conventional technique, when the oxide 105 is made plane by chemical mechanical polishing or etching etc., and during a subsequent cleaning process, the oxide and the edge of the wafer in the shallow trench area 100 will form oxide-recessed portions 106 which may result abnormal electricity conductivity, such as a double hump generated in ID/VG curves. Therefore, a method for forming a shallow trench isolation structure without forming oxide-recessed portions 106 must be provided.

U.S. Pat. No. 5,801,083 disclosed a method for forming insulation filler in trenches on a semiconductor substrate as shown in FIGS. 2A to 2C, it includes the following steps:

depositing a silicon oxide insulation layer 202 and a silicon nitride insulation layer 203 on the semiconductor substrate 201;

forming a photoresist layer 204 which has an opening 205 down into the silicon nitride insulation layer 203;

using the external photoresist layer 204 as a mask to etch the silicon oxide insulation layer 202 and the silicon nitride insulation layer 203 in a non-isotropic way;

forming a polymer spacer 206a on the photoresist layer 204, and forming a polymer spacer 206b on the lateral walls of the photoresist layer 204 and the silicon oxide insulation layer 202 and the silicon nitride insulation layer 203 as well as on the opening 205, so that an opening enveloped by the polymer can be formed;

dry etching the semiconductor substrate 201 to expose the opening enveloped by the polymer to form a shallow trench area 207; removing the photoresist layer 204 and the polymer spacer 206b to expose the non-etched area of the semiconductor substrate 201 as well as a sharp corner 208a;

making growing of a silicon oxide layer 209 on the exposed surfaces of the shallow trenches and the surface of non-etched area of the semiconductor substrate 201 to change the sharp corner 208a to a round corner 208b;

depositing an insulation layer 210 on the mixed insulation layer, and filling up the shallow trench area 207; and

removing the insulation layers 202 and 203 from the surface of the insulation layer 210.

The conventional method uses the polymer spacer 206b as a spacer, when the polymer spacer 206b is removed and insulation material is filled in, the space of the original spacer will be fully filled with the redundant insulation material 210 which is used exactly for protection of the corner 211.

However, steps of such a conventional technique are complicated, there is an additional process to form and to remove a polymer spacer, this inevitably increases the cost of the whole process. In view of the defect, the present invention is the first one to disclose using of a polysilicon layer in lieu of a silicon nitride (Si₃N₄) layer, and forming a spacer as a buffering layer by oxidation of polysilicon in oxidation of shallow trenches to protect insulation comers of the shallow trenches. This not only omits the process to form and to remove a polymer spacer, but also protects insulation corners of the shallow trenches by forming the spacer by oxidation of polysilicon, thereby avoids exposing of the STI comers which results abnormal electricity conductivity.

### SUMMARY OF THE INVENTION

The object of the present invention is to provide a method for protecting insulation comers of shallow trenches by forming spacers as buffering layers by oxidation of polysilicon. It includes the following steps:

a step for growing of a pad oxide layer: by providing a silicon substrate, the pad oxide layer is formed on the silicon substrate;

a step for growing of a polysilicon layer: the polysilicon layer is formed on the pad oxide layer;

a lithography and etching step: by using the lithography and etching process, a photoresist layer is formed to cover the surface area outside of the area forming shallow trenches, the photoresist layer is also formed on the polysilicon layer;

a step for forming of shallow trenches: the silicon substrate, the pad oxide layer and the polysilicon layer beneath the surface of the shallow trench area are etched to form a plurality of shallow trenches;

a photoresist layer removing step: the photoresist layer outside of the area of the shallow trenches is removed to expose the polysilicon layer;

a liner oxide layer forming step: the step simultaneously forms a liner oxide layer and a liner layer of oxide of polysilicon for the shallow trenches;

a filling step: a filling layer is formed on the liner oxide layer, the filling layer is insulating;

a step of making plane: the filling layer in the former step is made plane by chemical mechanical polishing (CMP);

a polysilicon layer removing step: the polysilicon layer exposed in the former step is removed by etching to expose the liner layer of oxide of polysilicon.

The present invention will be apparent in its objects and functions after reading the detailed description of the preferred embodiment thereof in reference to the accompanying drawings.

### BRIEF DESCRIPTION OF THE DRAWINGS

FIG. 1A to 1C are schematic views of a conventional shallow trench isolation (STI) structure;

FIG. 2A to 2C are also schematic views of a conventional shallow trench isolation (STI) structure, wherein, a spacer is used as a buffering layer to protect the insulation comers of shallow trenches;

FIG. 3A to 3J are schematic views showing the method of the present invention in forming a spacer as a buffering layer by oxidation of polysilicon for protecting insulation comers of shallow trenches.

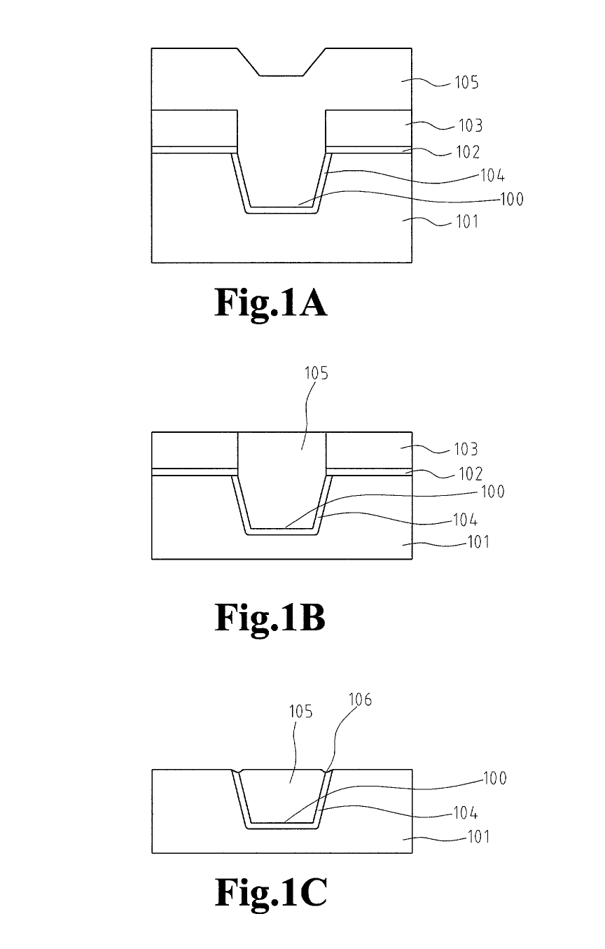

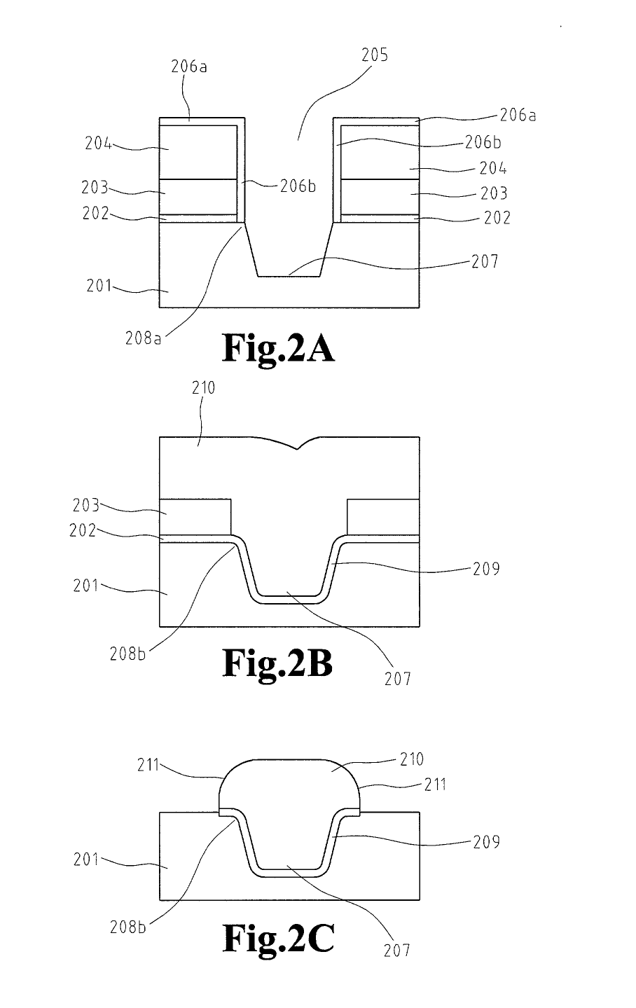

### DETAILED DESCRIPTION OF THE PREFERRED EMBODIMENT

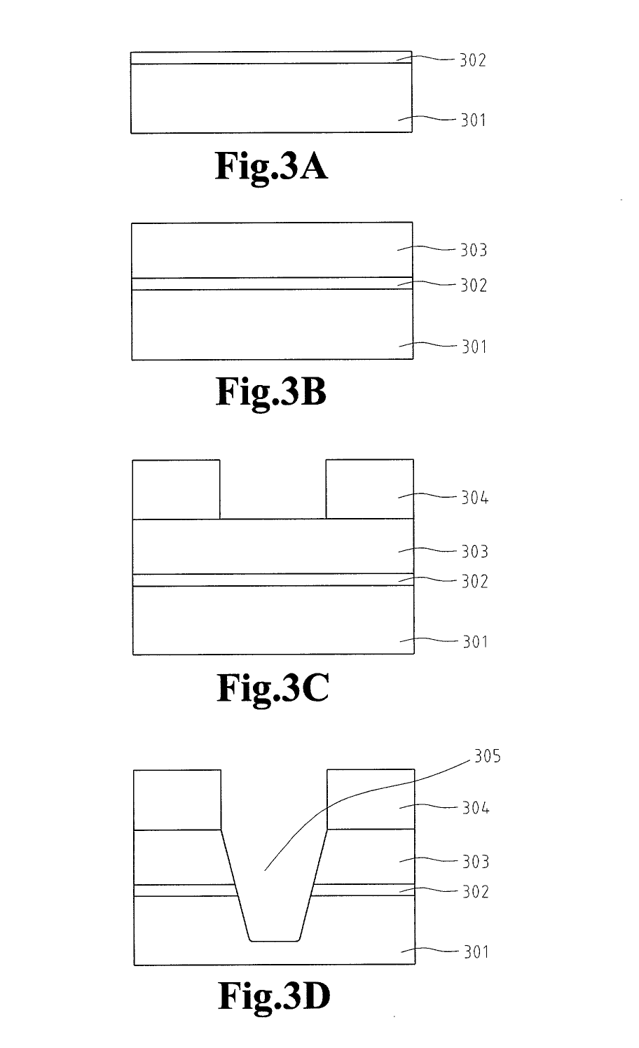

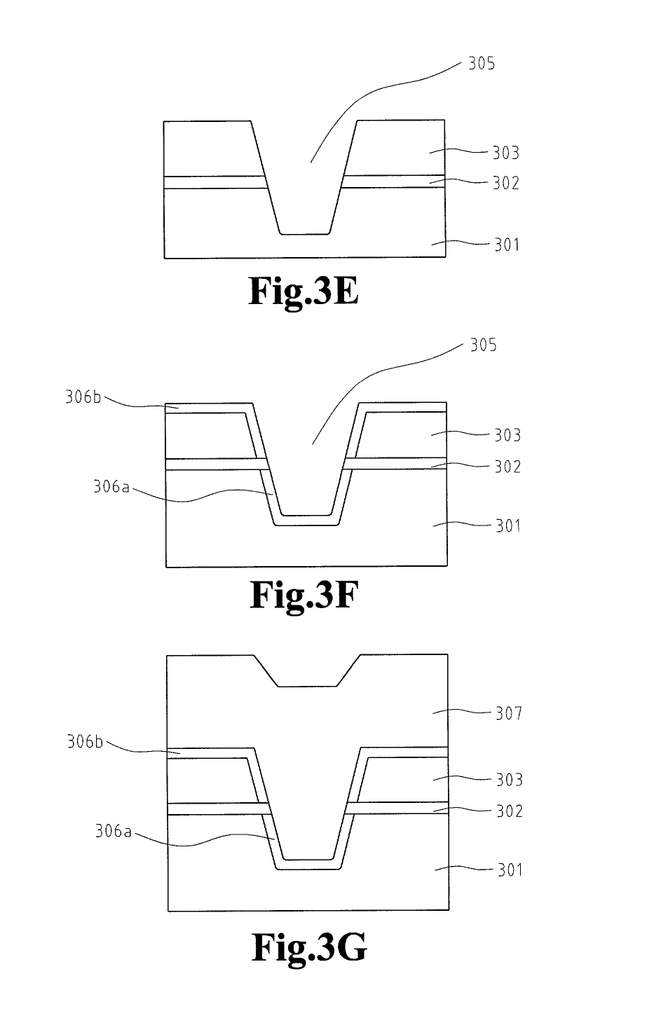

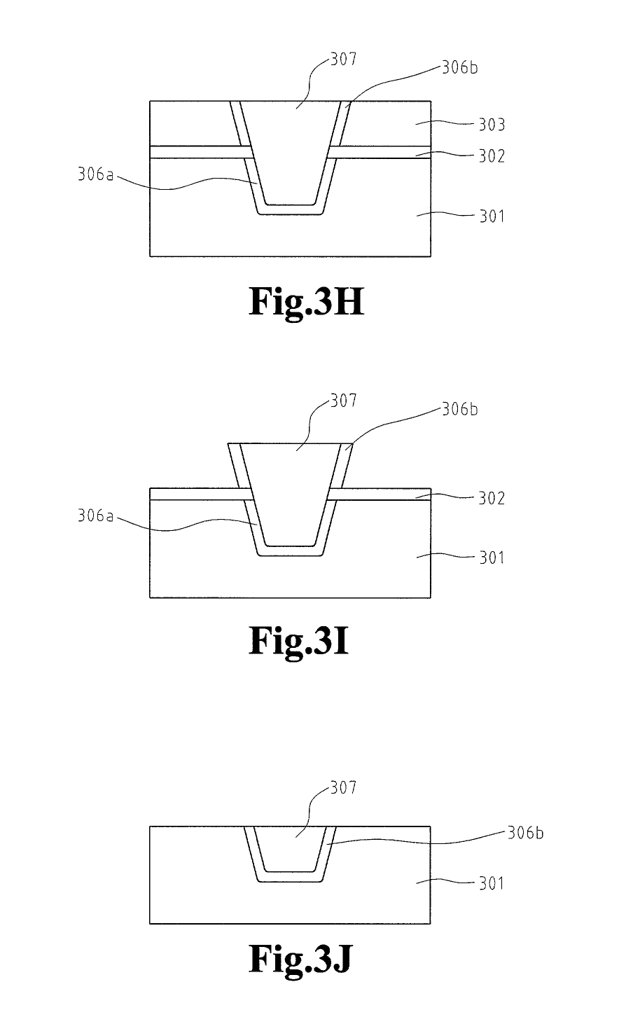

The present invention is a method for protecting insulation comers of shallow trenches by forming a spacer as a buffering layer by oxidation of polysilicon. As depicted in FIG. 3A to 3J showing the method of the present invention in forming a spacer as a buffering layer by oxidation of polysilicon for protecting insulation comers of shallow trenches, the method includes the following steps:

A step for growing of a pad oxide layer as depicted in FIG. 3A: by providing a silicon substrate 301, a pad oxide layer 302 is formed on the silicon substrate 301 which is a single crystal silicon wafer; the pad oxide layer 302 is formed on the silicon substrate 301 by growing by thermal oxidation under the condition of supplying oxygen, thickness of the pad oxide layer 302 can be 500-300 angstroms. In the most preferred embodiment of the present invention, thickness of the pad oxide layer 302 is 200 angstroms.

A step for growing of a polysilicon layer as depicted in FIG. 3B: a polysilicon layer 303 is formed on the pad oxide layer 302 by deposition; the deposition step is done by using SiH4 as a reactant to deposit the polysilicon layer 303 under the temperature of 580° C.-700° C., thickness of the polysilicon layer is about 1000-2000 angstroms.

A lithography and etching step as depicted in FIG. 3C: by using the lithography and etching process, a photoresist layer 304 is formed to cover the surface area outside of the area forming shallow trenches 305, the photoresist layer 304 is also formed on the polysilicon layer 303.

A step of forming shallow trenches as depicted in FIG. 3D: the silicon substrate, the pad oxide layer and the polysilicon layer beneath the surface of the shallow trench area are etched to form a plurality of shallow trenches 305; the step of forming uses the photoresist layer 304 as an etching mask, and the shallow trenches 305 are formed by dry etching.

A photoresist layer removing step as depicted in FIG. 3E: the photoresist layer 304 outside of the area of the shallow trenches 305 is removed to expose the polysilicon layer 303.

A liner oxide layer forming step as depicted in FIG. 3F: the step simultaneously forms a liner oxide layer 306a for the shallow trenches 305 and a liner layer of oxide of polysilicon 306b; wherein, the liner oxide layer 306a of the shallow trenches 305 is formed by forming oxide on the bottom and lateral walls of the shallow trenches 305, the liner layer of oxide of polysilicon 306b is formed by forming oxide on the surface and lateral walls of the polysilicon layer 303; the liner layer of oxide of polysilicon 306b formed on the lateral walls of the polysilicon layer 303 is functioned exactly as a buffering spacer, when the polysilicon layer 303 is removed, and when the wafer is to be made plane, the spacer can protect the insulation comers of the shallow trenches as a buffering spacer to avoid exposing of the insulation comers of the shallow trenches which may result abnormal electricity conductivity, and thickness of the liner oxide layer 306a is 100-300 angstroms.

A filling step as depicted in FIG. 3G: a filling layer 307 is formed on the liner layer of oxide of polysilicon 306b of the polysilicon layer 303 and the liner oxide layer 306a of the shallow trenches, the filling layer is insulating; wherein, the insulating filling layer can be made of silicon oxide, fluorine silicate glass (FSG), phosphosilicate glass (PSG), boron phosphosilicate glass (BPSG) or other dielectrics.

A step of making plane as depicted in FIG. 3H: the filling layer 307 in the former step is made plane by chemical mechanical polishing (CMP); and the polysilicon layer 303 is used as a terminating layer of polishing.

A polysilicon layer removing step as depicted in FIG. 31: the polysilicon layer 303 exposed in the former step is removed by wet etching by using hydrofluoric acid (HF) to expose the liner layer of oxide of polysilicon 306b; the liner layer of oxide of polysilicon 306b is functioned as a buffering spacer to protect the insulation comers of the shallow trenches and to avoid exposing of the insulation comers of the shallow trenches.

In conclusion, the method for protecting insulation corners of the shallow trenches by forming a spacer as a buffering layer by oxidation of polysilicon of the present invention can certainly get the expected object and effect, the present invention not only is a novel invention, but also is improved and industrial useful.

The above statement is only for illustrating a preferred embodiment of the present invention, and not for giving any limitation to the scope of the present invention. It will be apparent to those skilled in this art that all equivalent modifications and changes without departing from the spirit and principle of the present invention shall fall within the scope of the appended claims and are intended to form part of this invention.

What is claimed is:

1. A method for protecting insulation corners of shallow trenches by forming a spacer as a buffering layer by oxidation of polysilicon, including the following steps:
A. a step for growing of a pad oxide layer: by providing a silicon substrate, said pad oxide layer is formed on said silicon substrate;
B. a step for growing of a polysilicon layer: said polysilicon layer is formed on said pad oxide layer;
C. a lithography and etching step: by using said lithography and etching process, a photoresist layer is formed to cover the surface area outside of the area forming shallow trenches, said photoresist layer is also formed on said polysilicon layer;
D. a step of forming shallow trenches: said silicon substrate, said pad oxide layer and said polysilicon layer beneath the surface of said shallow trench area are etched to form said shallow trenches;
E. a photoresist layer removing step: said photoresist layer outside of the area of said shallow trenches is removed to expose said polysilicon layer;
F. a liner oxide layer forming step: said step simultaneously forms a liner oxide layer for said shallow trenches and a liner layer of oxide of polysilicon;
G. a filling step: said filling layer is formed on said liner oxide layer, said filling layer is insulating;
H. a step of making plane: said filling layer in the former step is made plane by chemical mechanical polishing (CMP);
I. a polysilicon layer removing step: said polysilicon layer exposed in the former step is removed by etching to expose said liner layer of oxide of polysilicon.

2. The method for protecting insulation comers of shallow trenches as in claim 1, wherein said pad oxide layer includes silicon oxide.

3. The method for protecting insulation comers of shallow trenches as in claim 1, wherein thickness of said pad oxide layer is 50-300 angstroms.

4. The method for protecting insulation corners of shallow trenches as in claim 1, wherein said polysilicon layer is formed on said pad oxide layer under the temperature of 580° C.-700° C. by using SiH4 as a reactant to deposit said polysilicon layer.

5. The method for protecting insulation comers of shallow trenches as in claim 1, wherein thickness of said polysilicon layer is 1000-2000 angstroms.

6. The method for protecting insulation comers of shallow trenches as in claim 1, wherein said liner oxide layer of said shallow trenches is formed by forming oxide on the bottom and lateral walls of said shallow trenches, said liner layer of oxide of polysilicon is formed by forming oxide on the surface and lateral walls of said polysilicon layer.

7. The method for protecting insulation comers of shallow trenches as in claim 1, wherein said liner oxide layer is formed on said silicon substrate by growing by thermal oxidation under the temperature of 950° C.-1150° C.

8. The method for protecting insulation comers of shallow trenches as in claim 1, wherein thickness of said liner oxide layer is 100-300 angstroms.

9. The method for protecting insulation comers of shallow trenches as in claim 1, wherein said filling layer is filled by High Density Plasma—Chemical Vapor Deposition (HDP-CVD).

10. The method for protecting insulation comers of shallow trenches as in claim 1, wherein said insulating filling layer is made of silicon oxide, fluorine silicate glass (FSG), phosphosilicate glass (PSG), boron phosphosilicate glass (BPSG) or other dielectrics.

11. The method for protecting insulation comers of shallow trenches as in claim 1, wherein said filling layer is made plane by chemical mechanical polishing (CMP); and said polysilicon layer is used as a terminating layer of polishing.

12. The method for protecting insulation comers of shallow trenches as in claim 1, wherein said polysilicon layer exposed is removed by wet etching by using hydrofluoric acid (HF).

13. The method for protecting insulation comers of shallow trenches as in claim 1, wherein the lateral wall of said exposed liner layer of oxide of polysilicon formed is functioned as a buffering spacer when said polysilicon layer is removed to protect said insulation comers of said shallow trenches.

14. A semiconductor structure made by said method as stated in claim 1, including:
a silicon substrate,
a pad oxide layer formed on said silicon substrate,
a polysilicon layer formed on said pad oxide layer,
a plurality of shallow trenches formed by etching on said silicon substrate,
said pad oxide layer and said polysilicon layer,
a liner oxide layer formed by forming oxide on the bottom and lateral walls of said shallow trenches, said oxide being formed also on the surface and lateral walls of said polysilicon layer.

15. The semiconductor structure as stated in claim 14, wherein said pad oxide layer includes silicon oxide.

16. The semiconductor structure as stated in claim 14, wherein thickness of said pad oxide layer is 50-300 angstroms.

17. The semiconductor structure as stated in claim 14, wherein thickness of said polysilicon layer is 1000-2000 angstroms.

18. The semiconductor structure as stated in claim 14, wherein thickness of said liner oxide layer is 100-300 angstroms.

19. The semiconductor structure as stated in claim 14, wherein said insulating filling layer is made of silicon oxide, fluorine silicate glass (FSG), phosphosilicate glass (PSG), boron phosphosilicate glass (BPSG) or other dielectrics.
